(19) United States
(12) Patent Application Publication
(10) Pub. No.: US 2024/0136990 A1
(43) Pub. Date: Apr. 25, 2024

(54) DISTRIBUTED CIRCUIT AND CONTROL METHOD THEREFOR

(71) Applicant: Nippon Telegraph and Telephone Corporation, Tokyo (JP)

(72) Inventors: Teruo Jo, Tokyo (JP); Munehiko Nagatani, Tokyo (JP); Hideyuki Nosaka, Tokyo (JP)

(21) Appl. No.: 18/546,634

(22) PCT Filed: Feb. 22, 2021
(86) PCT No.: PCT/JP2021/006569

§ 371 Date: Aug. 15, 2023

(51) Int. Cl. H03F 3/60

(52) U.S. Cl. CPC H03F 3/605; H03F 2200/12; H03F 2200/543

(57) ABSTRACT

A distributed circuit includes: a first transmission line that has an input end to which an input signal is input; a second transmission line that has an output end from which an output signal is output; a plurality of unit cells that are disposed along the first and second transmission lines, the input terminals of the unit cells being connected to the first transmission line, the output terminals of the unit cells being connected to the second transmission line; two input termination resistors connected in parallel to an end of the first transmission line; and two output termination resistors connected in parallel to an end of the second transmission line. In the distributed circuit, at least one input termination resistor is a temperature-gradient resistor, and voltages at the two input termination resistors are changed symmetrically.

### CROSS-REFERENCE TO RELATED APPLICATIONS

This application is a national phase entry of PCT Application No. PCT/JP2021/006569, filed on Feb. 22, 2021, which application is hereby incorporated herein by reference.

### TECHNICAL FIELD

The present invention relates to a distributed circuit that excels in frequency characteristics, and a method for controlling the distributed circuit.

### BACKGROUND

Wideband amplifiers are desired in various systems for high-speed communication, high-resolution radars, and the like. As a technique for widening the band of an amplifier, a distributed-type amplifier (hereinafter also referred to as “distributed amplifier”) 60 illustrated in FIG. 7 has been suggested (Non Patent Literature 1). By this technique, parasitic capacitances of transistors are incorporated into input and output transmission lines 621 and 622, to match impedances (normally 50Ω). Further, the propagation constants of the input and output transmission lines 621 and 622 are matched, so that wideband signal amplification becomes possible. To achieve preferred transmission characteristics in the distributed amplifier 60, it is important that the resistance values of termination resistors 63 and 64 are exactly 50Ω.

On the other hand, circuits that are actually manufactured are affected by process variation, and therefore, the resistance value of a termination resistor often deviates from the designed value. In a case where the resistance values of the input and output termination resistors of a distributed amplifier deviate from 50Ω, multiple reflection occurs, and ripples appear in the frequency characteristics. FIG. 8 shows the results of simulations of the frequency characteristics in a case where the value of the output termination resistor deviates from 50Ω. Ripples appear when the termination resistor is higher or lower than 50Ω.

To solve this problem, a mechanism capable of adjusting resistance values after the manufacturing is preferably provided. As illustrated in FIG. 9, a configuration including variable termination resistor circuits 73 and 74 that use metal-oxide-semiconductor field effect transistors (MOSFETs) as variable resistors has been suggested as a resistance value adjustment mechanism (Non Patent Literature 2). In this configuration, the gate voltages of the MOSFETs are adjusted to change the on-resistance between the drain and the source, and thus, the resistance values of the termination resistors are adjusted to 50Ω.

### CITATION LIST

### Non Patent Literature

Non Patent Literature 1: Jyo, Teruo, et al. “A 241-GHz-Bandwidth Distributed Amplifier with 10-dBm P1 dB in 0.25-μm InP DHBT Technology.” 2019 IEEE MTT-S International Microwave Symposium (IMS). IEEE, 2019.
Non Patent Literature 2: F. Zhang and P. Kinget, “Low power programmable-gain CMOS distributed LNA for ultra-wideband applications,” Digest of Technical Papers. 2005 Symposium on VLSI Circuits, 2005, Kyoto, Japan, 2005, pp. 78-81, doi:10.1109/VLSIC.2005.1469338.

### SUMMARY

### Technical Problem

However, there are parasitic capacitances in the MOSFETs, and therefore, the impedances drop as the frequency rises. This causes the resistance values to deviate from 50Ω on the high-frequency side in a case where the configuration using the MOSFETs is used for termination resistors.

Particularly, in a case where the variable termination resistor circuits 73 and 74 using the MOSFETs are used as the input and output termination resistors, it is necessary to use MOSFETs having a large current capacity and a large size. Therefore, the parasitic capacitances are also large, and the deviation of the resistance values from 50Ω becomes greater. FIG. 10 shows the result of a simulation of the frequency characteristics in a case where the variable termination resistor circuits 73 and 74 are used as the input and output termination resistors. In the frequency characteristics, it can be confirmed that ripples due to impedance mismatching appear on the high-frequency side.

As described above, in a case where MOSFETs are used to adjust the termination resistors to 50Ω, preferred frequency characteristics cannot be obtained due to the parasitic capacitances of the MOSFETs, and therefore, it is difficult to operate the amplifier in a wide band, which is a problem.

### Solution to Problem

To solve the above problem, a distributed circuit according to embodiments of the present invention includes: a first transmission line that has an input end to which an input signal is input; a second transmission line that has an output end from which an output signal is output; a plurality of unit cells that are disposed along the first and second transmission lines, the input terminals of the unit cells being connected to the first transmission line, the output terminals of the unit cells being connected to the second transmission line; two input termination resistors connected in parallel to an end of the first transmission line; and two output termination resistors connected in parallel to an end of the second transmission line. In the distributed circuit, at least one of the input termination resistors is a temperature-gradient resistor, at least one of the output termination resistors is a temperature-gradient resistor, voltages at the two input termination resistors are changed symmetrically, and voltages at the two output termination resistors are changed symmetrically.

### Advantageous Effects of Embodiments of Invention

According to embodiments of the present invention, it is possible to provide a distributed circuit that is capable of easily adjusting termination resistors and has excellent frequency characteristics, and a method for controlling the distributed circuit.

### BRIEF DESCRIPTION OF THE DRAWINGS

FIG. 1 is a circuit diagram illustrating a configuration of a distributed circuit according to a first embodiment of the present invention.

FIG. 2 is a graph illustrating the frequency characteristics of the distributed circuit according to the first embodiment of the present invention.

FIG. 3 is a circuit diagram illustrating a configuration of a distributed circuit according to a second embodiment of the present invention.

FIG. 4 is a circuit diagram illustrating a configuration of a distributed circuit according to a third embodiment of the present invention.

FIG. 5 is a circuit diagram illustrating a configuration of a distributed circuit according to a fourth embodiment of the present invention.

FIG. 6A is a circuit diagram illustrating an example configuration of a distributed circuit according to the present invention.

FIG. 6B is a circuit diagram of a unit cell in an example configuration of a distributed circuit according to the present invention.

FIG. 7 is a circuit diagram illustrating the configuration of a conventional distributed circuit.

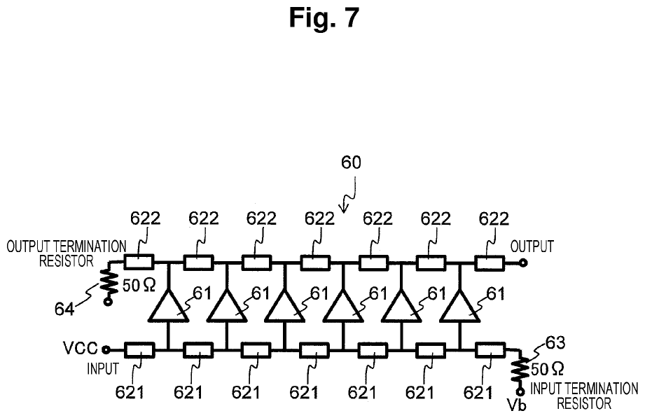

FIG. 8 is a diagram illustrating the frequency characteristics of the conventional distributed circuit.

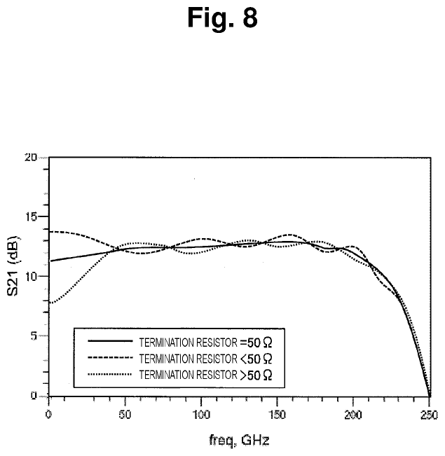

FIG. 9 is a circuit diagram illustrating the configuration of a conventional distributed circuit.

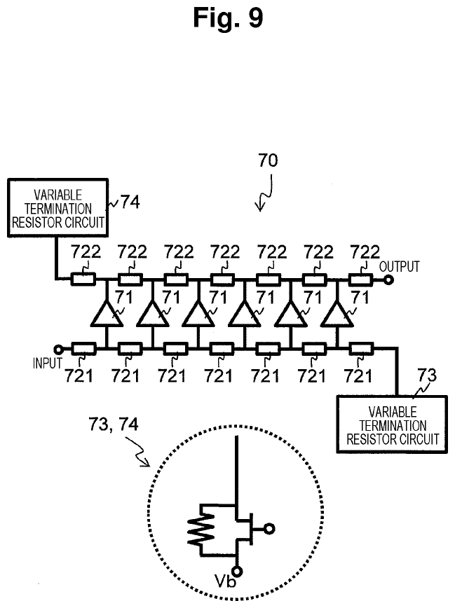

FIG. 10 is a diagram illustrating the frequency characteristics of the conventional distributed circuit.

### DETAILED DESCRIPTION OF ILLUSTRATIVE EMBODIMENTS

### First Embodiment

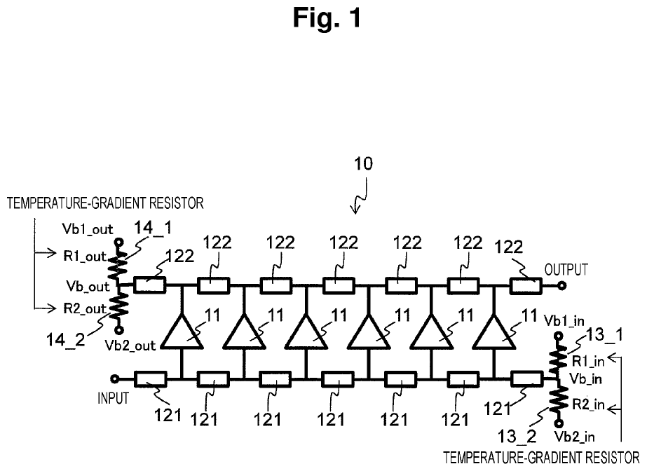

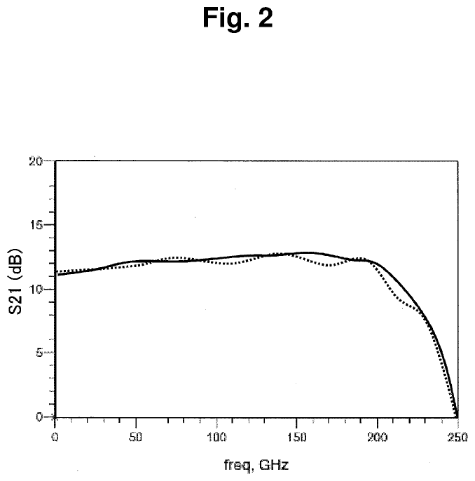

A distributed circuit and a method for controlling the distributed circuit according to a first embodiment of the present invention are now described, with reference to FIGS. 1 and 2.

### Configuration of a Distributed Circuit

As illustrated in FIG. 1, a distributed circuit 10 according to this embodiment includes unit cells 11, a first transmission line 121, a second transmission line 122, input termination resistors 13_1 and 13_2, and output termination resistors 14_1 and 14_2. A distributed amplifier is used for the distributed circuit 10 according to this embodiment.

An input signal is input to the input end of the first transmission line 121, and an output signal is output from the output end of the second transmission line 122. A plurality of unit cells 11 is arranged along the first and second transmission lines 121 and 122, the input terminals are connected to the first transmission line 121, and the output terminals are connected to the second transmission line 122. Here, the number of unit cells 11 may be one.

Further, the two input termination resistors 13_1 and 13_2 are connected in parallel to the end of the first transmission line 121, and the two output termination resistors 14_1 and 14_2 are connected in parallel to the end of the second transmission line 122.

Each of the input termination resistors 13_1 and 13_2 is a temperature-gradient resistor. Likewise, each of the output termination resistors 14_1 and 14_2 is a temperature-gradient resistor.

In the temperature-gradient resistors 13_1, 13_2, 14_1, and 14_2, self-heating changes the temperature and changes the resistance value, depending on the amount of the current to be applied. As temperature-gradient resistors are used as the termination resistors in this manner, it is possible to adjust the resistance value by changing the amount of the current to be applied.

To form the temperature-gradient resistors 13_1, 13_2, 14_1, and 14_2, the cross-sectional areas of the resistors are reduced, or the appropriate material is selected.

When the resistance value is adjusted here, two temperature-gradient resistors 13_1 and 13_2 and two temperature-gradient resistors 14_1 and 14_2 are arranged in parallel on the input side and the output side, respectively, so that the bias voltage of the unit cells 11 does not fluctuate. The voltages at a Vb1_in terminal and a Vb2_in terminal, and a Vb1_out terminal and a Vb2_out terminal at both ends of the two resistors are changed symmetrically so that the potentials at a Vb_in contact and a Vb_out contact at the midpoints of the two resistors do not fluctuate, and only the amount of the current to be applied is changed. In this manner, each combined resistance is adjusted to 50Ω at the time of an operation of the distributed circuit.

Here, “changing a voltage symmetrically” means that the bias voltage to be supplied to one terminal (the Vb1_in terminal, for example) is increased, and the bias voltage to be supplied to the other terminal (the Vb2_in terminal, for example) is lowered by the amount of the voltage increase. In other words, the bias voltages to be supplied to both terminals are changed so that the sum of the bias voltage to be supplied to one terminal (the Vb1_in terminal, for example) and the bias voltage to be supplied to the other terminal (the Vb2_in terminal, for example) becomes constant.

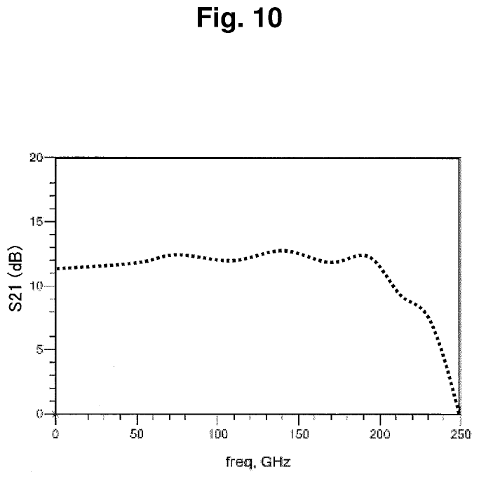

FIG. 2 illustrates the frequency characteristics (solid line) of the distributed circuit 10. For comparison, the frequency characteristics (dotted line as in FIG. 10) of a circuit that has a conventional mechanism using MOSFETs are also shown. In the frequency characteristics of the conventional mechanism, ripples are observed on the high-frequency side. In the frequency characteristics of the distributed circuit 10, on the other hand, ripples are not observed on the high-frequency side.

As described above, in the distributed circuit 10, unlike a conventional mechanism using MOSFETs, the resistance value adjustment mechanism using temperature-gradient resistors does not have a large parasitic capacitance. Accordingly, impedance deviation is small even on the high-frequency side, and thus, ripples in transmission characteristics can be prevented.

### Method for Controlling the Distributed Circuit

The following is a description of a method for controlling the distributed circuit (distributed amplifier) 10 according to this embodiment.

In the distributed amplifier 10, the resistor 13_1 (hereinafter referred to as R1_in) and the resistor 13_2 (hereinafter referred to as R2_in), which are temperature-gradient resistors, are disposed on the input side. Likewise, the resistor 141 (hereinafter referred to as R1_in) and the resistor 14_2 (hereinafter referred to as R2_in), which are temperature-gradient resistors, are disposed on the output side.

R1_in and R2_in are designed so that the combined resistance of the two temperature-gradient resistors viewed from the Vb_in contact becomes 50Ω. Likewise, R1_out and R2_out are designed so that the combined resistance of the two temperature-gradient resistors viewed from the Vb_out contact becomes 50Ω. For example, when the respective values of R1_in and R2_in are set to 100Ω, the combined resistance is 50Ω. However, during the designing, the resistance value of each temperature-gradient resistor is designed on the basis of the resistance value at the time when the amount of the current to be applied becomes the intermediate value in the adjustment range.

When the amount of the current to be applied to the temperature-gradient resistors is changed, the DC bias of each unit cell 11 is determined by the DC potentials at the Vb_in contact and the Vb_out contact. Therefore, it is necessary not to fluctuate the voltages at the Vb_in contact and the Vb_out contact.

Here, the amount of the current to be applied to the temperature-gradient resistors is changed, without any fluctuation in the DC potentials at the Vb_in contact (the midpoint between R1_in and R2_in) and the Vb_out contact (the midpoint between R1_out and R2_out) as described below.

For example, in a case where the DC voltage at the Vb_in contact is set to Vdc_in, and the current flowing from the Vb1_in terminal to the Vb2_in terminal via R1_in and R2_in is set to Idc_in, the voltage at the Vb2_in terminal is set to (Vdc_in−Idc_in×R2_in), and the voltage at the Vb1_in terminal is set to (Vdc_in +Idc_in×R1_in).

Also, in a case where the DC voltage at the Vb_out contact is set to Vdc_out, and the current flowing from the Vb1_out terminal to the Vb2_out terminal via R1_out and R2_out is set to Idc_out, the voltage at the Vb2_out terminal is set to (Vdc_out−Idc_out×R2_out), and the voltage at the Vb1_out terminal is set to (Vdc_out+Idc_out×R1_out).

As a result, any current is not injected from the Vb_in contact into the core circuit.

If a current is injected from the Vb_in contact into the core circuit, the relational expressions of the voltages at the respective terminals of Vb1_in, Vb2_in, Vb1_out, and Vb2_out described above are not true, the DC voltage values deviate, and the current values deviate. Since R1 and R2 change with the temperature-gradient resistors, the current to be injected from the Vb_in contact into the core circuit cannot be calculated. Therefore, the amount of the current to be applied to the temperature-gradient resistors cannot be determined without any fluctuation in the DC potentials of Vb_in (the potential at the midpoint) and Vb_out.

In this manner, the distributed circuit 10 according to this embodiment is based on the premise that any current is not applied from the input and output termination resistors to the core circuit side (each unit cell 11).

As described above, with the distributed circuit and the method for controlling the distributed circuit according to this embodiment, the termination resistors can be easily adjusted through current injection into the temperature-gradient resistors, and thus, excellent frequency characteristics can be provided.

### Second Embodiment

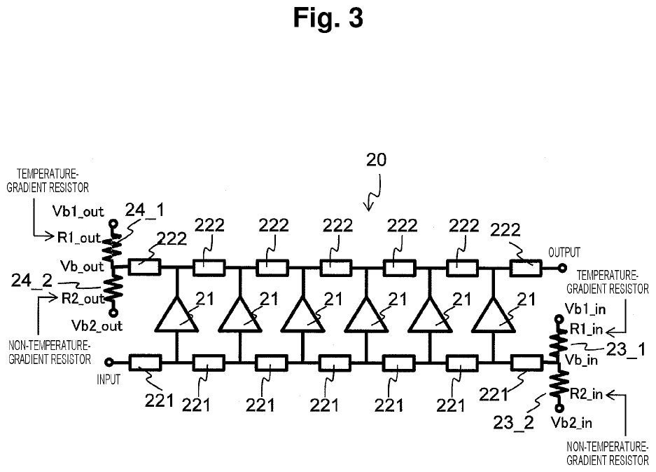

A distributed circuit and a method for controlling the distributed circuit according to a second embodiment of the present invention are now described, with reference to FIG. 3. A distributed circuit 20 according to this embodiment has substantially the same configuration as the distributed circuit 10 according to the first embodiment, but differs in the configuration of the input and output termination resistors.

### Configuration of a Distributed Circuit

As illustrated in FIG. 3, the distributed circuit 20 according to this embodiment includes unit cells 21, a first transmission line 221, a second transmission line 222, input termination resistors 23_1 and 23_2, and output termination resistors 24_1 and 24_2.

In the input termination resistors 23_1 and 23_2, one resistor (the resistor 23_1, for example) is a temperature-gradient resistor, and the other resistor (the resistor 23_2, for example) is a non-temperature-gradient resistor. Likewise, in the output termination resistors 24_1 and 24_2, one resistor (the resistor 24_1, for example) is a temperature-gradient resistor, and the other resistor (the resistor 24_2, for example) is a non-temperature-gradient resistor.

The amount of the current to be applied is changed, so that the resistance values of the temperature-gradient resistors 23_1 and 24_1 can be adjusted, as in the first embodiment.

On the other hand, the resistances of the non-temperature-gradient resistors 23_2 and 24_2 do not change with the amount of the current to be applied, and do not have any temperature gradient. To form the non-temperature-gradient resistors 23_2 and 24_2, the cross-sectional areas of the resistors are increased, or the appropriate material is selected.

As described above, in the distributed circuit 20, the input and output termination resistors are formed with the temperature-gradient resistors 23_1 and 24_1, and the non-temperature-gradient resistors 23_2 and 24_2, the respective combined resistances thereof are 50Ω, and the resistance values of the temperature-gradient resistors are adjusted with the amount of the current to be applied.

Here, the resistance values of the non-temperature-gradient resistors 23_2 and 24_2 do not change, and accordingly, the current Icore flowing to the core circuit side can be determined by calculation in advance. This aspect is described in detail below.

### Method for Controlling the Distributed Circuit

In the distributed circuit 20, the amount of the current to be applied to the temperature-gradient resistors is changed, without any fluctuation in the DC potentials at the Vb_in contact and the Vb_out contact as described below. Here, the voltages at the Vb1_in terminal and the Vb2_in terminal, and the Vb1_out terminal and the Vb2_out terminal at both ends of the two resistors are changed symmetrically, so that only the amount of the current to be applied is changed.

For example, in a case where the termination resistors on the input side are formed with the temperature-gradient resistor 23_1 (hereinafter referred to as R1_in) and the non-temperature-gradient resistor 23_2 (hereinafter referred to as R2_in), if the DC voltage at the Vb_in contact is set to Vdc_in, and the current to be applied to the temperature-gradient resistor R1_in is set to Idc_in, the voltage at the Vb2_in terminal is set to [Vdc_in−(Idc_in−Icore_in)×R2_in], and the voltage at the Vb1_in terminal is set to (Vdc_in +Idc_in×R1_in).

However, I_core_in is the current flowing to the input terminal side (the core circuit side) of the circuit (the current being the total current flowing to the inputs of all the unit cells 21), and Idc_in >I_core_in. Here, Idc_in flowing to the temperature-gradient resistor R1_in is divided into Icore_in flowing to the core circuit side and the current flowing to R2_in.

Also, in a case where the termination resistors on the output side are formed with the temperature-gradient resistor 24_1 (hereinafter referred to as R1_out) and the non-temperature-gradient resistor 24_2 (hereinafter referred to as R2_out), if the DC voltage at the Vb_out contact is set to Vdc_out, and the current to be applied to the temperature-gradient resistor is set to Idc_out, the voltage at the Vb2_out terminal is set to [Vdc_out−(Idc_out−I_core_out)×R2_out], and the voltage at Vb1_out is set to (Vdc_out+Idc_out×R1_out).

However, I_core_out is the current flowing to the output terminal side (the core circuit side) of the circuit (the current being the total current flowing to the outputs of all the unit cells 21), and Idc_out>I_core_out. Here, Idc_out flowing to the temperature-gradient resistor R1_out is divided into I_core_out flowing to the core circuit side and the current flowing to R2_out.

As described above, with the distributed circuit and the method for controlling the distributed circuit according to this embodiment, the termination resistors can be easily adjusted through current injection into the temperature-gradient resistors while a current is being injected from the Vb_in contact and the Vb_out contact into the core circuit. Thus, excellent frequency characteristics can be provided. In other words, the distributed circuit can be used in a case where it is necessary to apply a current (supply a current) from the input and output termination resistors to the core circuit side (each unit cell 21).

### Third Embodiment

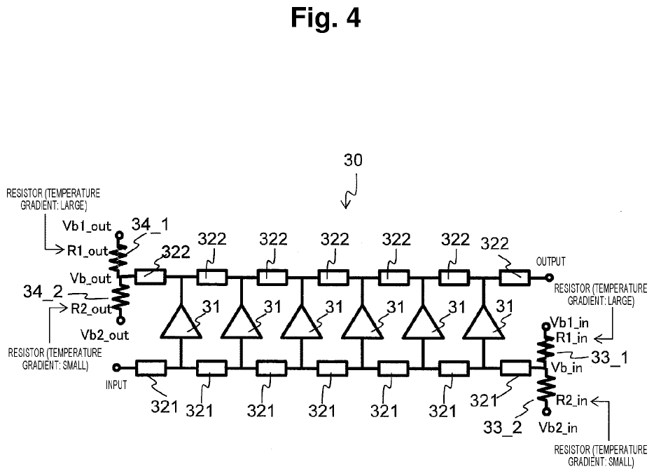

A distributed circuit and a method for controlling the distributed circuit according to a third embodiment of the present invention are now described, with reference to FIG. 4. A distributed circuit 30 according to this embodiment has substantially the same configuration as the distributed circuits according to the first and second embodiments, but differs in the configuration of the input and output termination resistors.

### Configuration of a Distributed Circuit

As illustrated in FIG. 4, the distributed circuit 30 according to this embodiment includes unit cells 31, a first transmission line 321, a second transmission line 322, input termination resistors 33_1 and 33_2, and output termination resistors 34_1 and 34_2.

In the input termination resistors 33_1 and 33_2, one resistor (the resistor 33_1, for example) is a temperature-gradient resistor having a large temperature gradient, and the other resistor (the resistor 33_2, for example) is a temperature-gradient resistor having a small temperature gradient. In this manner, between the input termination resistors, the temperature gradient of the other resistor is smaller than that of the one resistor.

Likewise, in the output termination resistors 34_1 and 34_2, one resistor (the resistor 34_1, for example) is a temperature-gradient resistor having a large temperature gradient, and the other resistor (the resistor 34_2, for example) is a temperature-gradient resistor having a small temperature gradient. In this manner, between the output termination resistors, the temperature gradient of the other resistor is smaller than that of the one resistor.

Here, the magnitudes of the temperature gradients in the temperature-gradient resistors are adjusted with the cross-sectional areas (particularly the widths) of the resistors and the material. For example, as the width of the resistance is made smaller, the temperature gradient becomes larger.

As described above, in the distributed circuit 30, the input and output termination resistors are formed with the temperature-gradient resistors 33_1 and 34_1 with large temperature gradients, and the temperature-gradient resistors 33_2 and 34_2 with small temperature gradients, the respective combined resistances thereof are 50Ω, and the resistance values of the temperature-gradient resistors are adjusted with the amount of the current to be applied.

### Method for Controlling the Distributed Circuit

A method for changing the amount of the current to be applied to the temperature-gradient resistors without causing any fluctuation in the DC potentials of Vb_in and Vb_out in the distributed circuit 30 is described below. Here, the voltages at the Vb1_in terminal and the Vb2_in terminal, and the Vb1_out terminal and the Vb2_out terminal at both ends of the two resistors are changed symmetrically, so that only the amount of the current to be applied is changed.

For example, in a case where the termination resistors on the input side are formed with the temperature-gradient resistor 331 (hereinafter referred to as R1_in) having a large temperature gradient and the temperature-gradient resistor 33_2 (hereinafter referred to as R2_in) having a small temperature gradient, if the DC voltage at the Vb_in contact is set to Vdc_in, and the current to be applied to the resistor with the large temperature gradient is set to Idc_in, the voltage at the Vb2_in terminal is set to [Vdc_in−(Idc_in−Icore_in)×R2_in], and the voltage at the Vb1_in terminal is set to (Vdc_in +Idc_in×R1_in).

However, I_core_in is the current flowing to the input side of the circuit (the current being the total current flowing to the inputs of all the unit cells 31), and Idc_in >I_core_in.

Also, in a case where the termination resistors on the output side are formed with the temperature-gradient resistor 34_1 (hereinafter referred to as R1_out) having a large temperature gradient and the temperature-gradient resistor 34_2 (hereinafter referred to as R2_out) having a small temperature gradient, if the DC voltage at the Vb_out contact is set to Vdc_out, and the current to be applied to the resistor having the large temperature gradient is set to Idc_out, the voltage at the Vb2_out terminal is set to [Vdc_out−(Idc_out−I_core_out)×R2_out], and the voltage at the Vb1_out terminal is set to (Vdc_out+Idc_out×R1_out).

However, I_core_out is the current flowing to the output side of the circuit (the current being the total current flowing to the outputs of all the unit cells 31), and Idc_out>I_core_out.

As described above, with the distributed circuit and the method for controlling the distributed circuit according to this embodiment, the termination resistors can be adjusted through current injection into the temperature-gradient resistors while a current is being injected from the Vb_in contact and the Vb_out contact into the core circuit, as in the second embodiment. Thus, excellent frequency characteristics can be provided. The distributed circuit according to this embodiment can be used in a case where it is necessary to apply a current (supply a current) from the input and output termination resistors to the core circuit side (each unit cell 31), and it is difficult to form non-temperature-gradient resistors.

### Fourth Embodiment

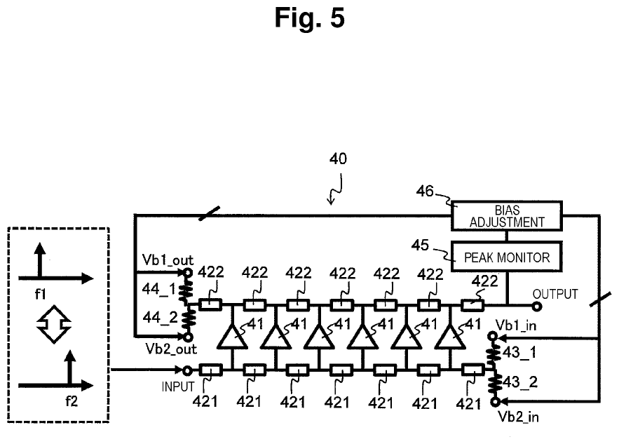

A distributed circuit and a method for controlling the distributed circuit according to a fourth embodiment of the present invention are now described, with reference to FIG. 5. A distributed circuit 40 according to this embodiment has substantially the same configuration as the distributed circuit 10 according to the first embodiment, and further includes a component that performs bias adjustment using a peak monitor.

A method for evaluating whether the resistance values of the termination resistors are correctly set in the distributed circuits according to the first to third embodiments may be a method using a frequency-sweep measuring device such as a VNA. By this method, the input/output frequency characteristics of a distributed amplifier are monitored with a VNA, and the resistance values of the termination resistors are adjusted so that ripples of S-parameter S21 are minimized. However, a frequency-sweep measuring device such as a VNA is expensive.

### Configuration of a Distributed Circuit

As illustrated in FIG. 5, the distributed circuit according to this embodiment includes unit cells 41, a first transmission line 421, a second transmission line 422, input termination resistors 43_1 and 43_2, and output termination resistors 44_1 and 44_2.

Each of the input termination resistors 43_1 and 43_2 is a temperature-gradient resistor. Likewise, each of the output termination resistors 44_1 and 44_2 is a temperature-gradient resistor.

Further, a peak monitor 45 and a bias adjustment mechanism 46 are connected to the output terminal. The output of the bias adjustment mechanism 46 is connected to the input termination resistors 43_1 and 43_2 and the output termination resistors 44_1 and 44_2.

### Method for Controlling the Distributed Circuit

The following is a description of a method for controlling the distributed circuit 40 according to this embodiment.

First, single-frequency signals at two frequencies f1 and f2 are alternately input to the distributed circuit 40 at predetermined time intervals.

Next, at the output of the distributed circuit 40, the magnitude of the amplitude of each of the two single-frequency signals (frequencies f1 and f2) is measured by the peak monitor 45.

Lastly, the bias adjustment mechanism 46 performs bias adjustment so as to minimize the amplitude difference between the two single-frequency signals (frequencies f1 and f2), adjusts the current to be applied to the input termination resistors 43_1 and 43_2 and the output termination resistors 44_1 and 44_2, and thus, adjusts the input and output termination resistors.

Here, a method for selecting the frequencies f1 and f2 is described. The cycles of ripple swings change with the electrical length of the input or output transmission line.

Since the electrical length is known at the stage of designing, the frequencies corresponding to the valleys and the peaks (the maximum value and the minimum value) of the swings are set as the frequencies f1 and f2. For example, in the case of a transmission line having an electrical length of L (m), a swing cycle fp is fp=c/2L, and accordingly, (f1, f2)=n×(c/4L, c/2L). Here, n is an integer of 1 or greater, and c represents the speed of light.

With the distributed circuit and the method for controlling the distributed circuit according to this embodiment, the values of the termination resistors can be easily set to optimum values at low cost without an expensive frequency-sweep measuring device, and excellent frequency characteristics can be provided.

In the example described above, this embodiment is applied to a distributed circuit according to the first embodiment. However, this embodiment is not necessarily applied to the first embodiment, but may be applied to distributed circuits according to the second and third embodiments.

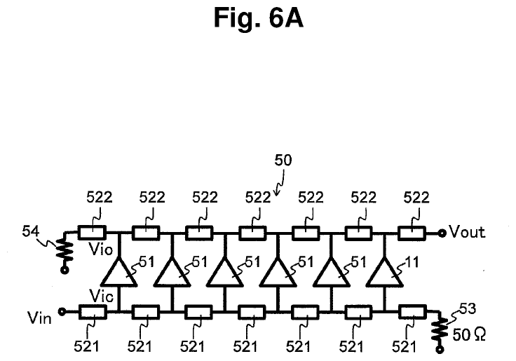

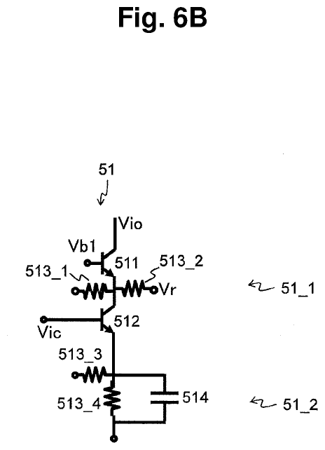

In the examples described in the embodiments of the present invention, a distributed circuit is a distributed amplifier, but is not necessarily a distributed amplifier. For example, as illustrated in FIGS. 6A and 6B, the present invention can also be applied in a case where a variable gain circuit 51_1 is used in a unit cell 51 or in a case where a degeneration circuit 51_2 is used. The present invention can also be applied to other distributed circuits, such as a distributed mixer and a distributed voltage-controlled oscillator (VCO).

In the embodiments of the present invention, examples of the structure, the dimension, the material, and the like of each component have been described regarding the configurations of distributed circuits, methods for controlling the distributed circuits, and the like. However, the present invention is not limited to these examples. A distributed circuit is only required to exhibit its functions and achieve effects.

### INDUSTRIAL APPLICABILITY

The present invention can be applied to devices and electronic circuits of devices to be used for optical communication, wireless communication, radar sensing, and the like.

### REFERENCE SIGNS LIST

10 distributed circuit
11 unit cell
121, 122 transmission line
13_1, 13_2 input termination resistor
14_1, 14_2 output termination resistor

1-10. (canceled)

11. A distributed circuit comprising:
a first transmission line that has an input end configured to receive an input signal;
a second transmission line that has an output end configured to output an output signal;
a plurality of unit cells that are disposed along the first and second transmission lines, input terminals of the plurality of unit cells being connected to the first transmission line, output terminals of the plurality of unit cells being connected to the second transmission line;
two input termination resistors connected in parallel to an end of the first transmission line; and
two output termination resistors connected in parallel to an end of the second transmission line,
wherein at least one of the two input termination resistors is a temperature-gradient resistor,
wherein at least one of the two output termination resistors is a temperature-gradient resistor,
wherein voltages at the two input termination resistors are configured to be changed symmetrically, and
wherein voltages at the two output termination resistors are configured to be changed symmetrically.

12. The distributed circuit according to claim 11, wherein a combined resistance of the two input termination resistors is 50Ω, and a combined resistance of the two output termination resistors is 50Ω.

13. The distributed circuit according to claim 11, wherein the two input termination resistors are temperature-gradient resistors, the two output termination resistors are temperature-gradient resistors, and no currents flow from the two input termination resistors and the two output termination resistors to the unit cells.

14. The distributed circuit according to claim 11, wherein one input termination resistor of the two input termination resistors does not have a temperature gradient, and one output termination resistor of the two output termination resistors does not have a temperature gradient.

15. The distributed circuit according to claim 11, wherein a temperature gradient of a first input termination resistor of the two input termination resistors is smaller than a temperature gradient of a second input termination resistor of the two input termination resistors, and a temperature gradient of a first output termination resistor of the two output termination resistors is smaller than a temperature gradient of a second output termination resistor of the two output termination resistors.

16. The distributed circuit according to claim 11, further comprising:
a peak monitor configured to measure amplitudes of two single-frequency signals that are input at different times and have different frequencies; and
a bias adjustment mechanism configured to adjust a current to be supplied to the two input termination resistors to minimize an amplitude difference between the two single-frequency signals.

17. The distributed circuit according to claim 16, wherein:
f1 is n×c/4L
f2 is n×c/2L, and
f1 and f2 represent frequencies of the two single-frequency signals, L represents an electrical length of the first transmission line and the second transmission line, c represents a speed of light, and n represents an integer of 1 or greater.

18. A method for controlling a distributed circuit, the method comprising:
setting a voltage at a first input termination resistor terminal to (Vdc_in +Idc_in×R1_in), wherein the distributed circuit comprises:
a first transmission line that has an input end configured to receive an input signal;
a second transmission line that has an output end configured to output an output signal;
a plurality of unit cells that are disposed along the first and second transmission lines, input terminals of the plurality of unit cells being connected to the first transmission line, output terminals of the plurality of unit cells being connected to the second transmission line;
two input termination resistors connected in parallel to an end of the first transmission line;
two output termination resistors connected in parallel to an end of the second transmission line, wherein at least one of the two input termination resistors is a temperature-gradient resistor, wherein at least one of the two output termination resistors is a temperature-gradient resistor, wherein voltages at the two input termination resistors are configured to be changed symmetrically, and wherein voltages at the two output termination resistors are configured to be changed symmetrically;
the first input termination resistor terminal connected to a first input termination resistor of the two input termination resistors;
a second input termination resistor terminal connected to a second input termination resistor of the two input termination resistors;
an input-side contact to which the first input termination resistor and the second input termination resistor are connected;
a first output termination resistor terminal connected to a first output termination resistor of the two output termination resistors;
a second output termination resistor terminal connected to a second output termination resistor of the two output termination resistors; and
an output-side contact to which the first output termination resistor and the second output termination resistor are connected;
setting a voltage at the second input termination resistor terminal to (Vdc_in −Idc_in× R2_in);
setting a voltage at the first output termination resistor terminal to (Vdc_out+Idc_out×R1_out); and
setting a voltage at the second output termination resistor terminal to (Vdc_out−Idc_out×R2_out),
wherein Vdc_in represents a voltage at the input-side contact, Idc_in represents a current at the input-side contact, R1_in represents resistance of the first input termination resistor, R2_in represents resistance of the second input termination resistor, Vdc_out represents a voltage at the output-side contact, Idc_out represents a current at the output-side contact, R1_out represents a resistance of the first output termination resistor, and R2_out represents a resistance of the second output termination resistor.

19. The method for controlling a distributed circuit according to claim 18, wherein the two input termination resistors are temperature-gradient resistors, the two output termination resistors are temperature-gradient resistors, and no currents flow from the two input termination resistors and the two output termination resistors to the unit cells.

20. The method for controlling the distributed circuit according to claim 18, wherein a combined resistance of the two input termination resistors is 50Ω, and a combined resistance of the two output termination resistors is 50Ω.

21. The method for controlling the distributed circuit according to claim 18, further comprising:
measuring amplitudes of two single-frequency signals that are input at different times and have different frequencies; and
adjusting a bias adjustment mechanism, to minimize an amplitude difference between the two single-frequency signals.

22. A method for controlling a distributed circuit, the method comprising:
setting a voltage at a first input termination resistor terminal to (Vdc_in +Idc_in×R1_in), wherein the distributed circuit comprises:
a first transmission line that has an input end configured to receive an input signal;
a second transmission line that has an output end configured to output an output signal;
a plurality of unit cells that are disposed along the first and second transmission lines, input terminals of the plurality of unit cells being connected to the first transmission line, output terminals of the plurality of unit cells being connected to the second transmission line;
two input termination resistors connected in parallel to an end of the first transmission line;
two output termination resistors connected in parallel to an end of the second transmission line, wherein at least one of the two input termination resistors is a temperature-gradient resistor, wherein at least one of the two output termination resistors is a temperature-gradient resistor, wherein voltages at the two input termination resistors are configured to be changed symmetrically, and wherein voltages at the two output termination resistors are configured to be changed symmetrically;
a first input termination resistor terminal connected to a first input termination resistor of the two input termination resistors;
a second input termination resistor terminal connected to a second input termination resistor of the two input termination resistors;
an input-side contact to which the first input termination resistor and second other input termination resistor are connected;
a first output termination resistor terminal connected to a first output termination resistor;
a second output termination resistor terminal connected to a second output termination resistor; and
an output-side contact to which the first output termination resistor and the second output termination resistor are connected;
setting a voltage at the second input termination resistor terminal to [Vdc_in −(Idc_in−Icore_in)×R2_in];
setting a voltage at the first output termination resistor terminal to (Vdc_out+Idc_out×R1_out); and
setting a voltage at the second output termination resistor terminal to [Vdc_out−(Idc_out−I_core_out)×R2_out], wherein Vdc_in represents a voltage at the input-side contact, Idc_in represents a current at the input-side contact, Icore_in represents a current flowing from the input-side contact to a side of the unit cells, R1_in represents a resistance of the first input termination resistor, R2_in represents a resistance of the second input termination resistor, Vdc_out represents a voltage at the output-side contact, Idc_out represents a current at the output-side contact, Icore_out represents a current flowing from the output-side contact to the side of the unit cells, R1_out represents a resistance of the first output termination resistor, and R2_out represents a resistance of the second output termination resistor.

23. The method for controlling the distributed circuit according to claim 22, wherein one input termination resistor of the two input termination resistors does not have a temperature gradient, and one output termination resistor of the two output termination resistors does not have a temperature gradient.

24. The method for controlling the distributed circuit according to claim 22, wherein a combined resistance of the two input termination resistors is 50Ω, and a combined resistance of the two output termination resistors is 50Ω.

25. The method for controlling the distributed circuit according to claim 22, further comprising:
measuring amplitudes of two single-frequency signals that are input at different times and have different frequencies; and
adjusting a bias adjustment mechanism, to minimize an amplitude difference between the two single-frequency signals.
